(19) United States
(12) Patent Application Publication
(10) Pub. No.: US 2012/0193232 A1
(43) Pub. Date: Aug. 2, 2012

(54) PREPARATION METHOD OF ANTI-BACTERIAL COATING ON PLASTIC SURFACE

(75) Inventors: Shui Yu, Xiamen (CN); Min-Zen Lee, Xiamen (CN)

(73) Assignee: Xiamen Runner Industrial Corporation

(21) Appl. No.: 13/352,440

(22) Filed: Jan. 18, 2012

(30) Foreign Application Priority Data
Jan. 28, 2011 (CN) 201110032747.1

(51) Int. Cl. C25B 7/00; C23C 16/06; C08F 2/48; C23C 14/34; B05D 1/36

(52) U.S. Cl. 204/478; 204/471; 204/192.1; 204/192.15; 427/470; 427/508; 427/250

(57) ABSTRACT

The present invention is a preparation method of an anti-bacterial coating on a plastic surface. A preparation method of an anti-bacterial coating on a plastic surface with a better anti-bacterial effect is provided and comprises putting a plastic substrate into a PVD vacuum device; coating an anti-bacterial metallic layer on the plastic surface; and spray coating an anti-bacterial middle coating on the sample coated with anti-bacterial metallic coating. Utilizing PVD to coat antibacterial layer offsets timeliness of bacterial activity of the organic anti-bacterial coating, which allows the products with double bacterial layers have excellent anti-bacterial and bacteria-inhibited effects during their life spans. The anti-bacterial effect can not only be lasted for a long time, but also achieve high anti-bacterial efficiency (antibacterial rate is more than 99%). The product has excellent function and superior appearance, which is suitable for bath products, electronic devices, domestic appliances, cars and other industries.

### BACKGROUND OF THE INVENTION

1. Field of the Invention

The present invention is related to a plastic material, particularly to a preparation method of an anti-bacterial coating on a plastic surface.

2. Description of Related Art

Since 21^{st} century, plastic products have become essential parts in people's daily lives. They are broadly applied for every detail in our lives. For example, every kind of domestic electronic appliance (telephone, wash machine, computers, switches for electronic appliances) have used a large numbers of plastic products. On the other hand, due to the influences stemmed from environmental pollution and other causes, surfaces of these plastic products that people daily use often have a large number of bacteria, which become bacterial contamination source and source of infection of diseases. Statistically, among the death toll each year all over the world, 17 million people died for bacterial infection. Therefore, to develop and research products having novel coatings with anti-bacterial function have significant practical meanings in terms of improving people's surroundings, decreasing incidence of diseases, protecting human health and so forth.

Since 2003, SARS virus prevailed over the world and then H1N1 influenza erupted globally, so that consumers' worries about food safety and every pathogen existing in the environment dramatically increased. Anti-bacterial agents applied in plastics all over the world increase approximately 3.5%˜4% each year. North America is the area who uses the largest amount of anti-bacterial agents (including biostat), which occupies 40% of total quantity used all over the world while Japan occupies approximately 20%. The average amount of anti-bacterial agents for Japanese is the largest and overwhelms that for North American and European. According to a survey recently published by the well-known survey cooperation all over the world, Gallup Poll, mot consumers expressed that they are willing to buy anti-bacterial products and 75% of consumers preferred the products with anti-bacterial function. In the survey, 7 out of 10 people revealed they use over 6 kinds of antibacterial products. Consumers consider it is necessary to use anti-bacterial products in use and environmental aspects.

CN200420071581 published a product with anti-bacterial and wear-resisting surfaces. Its substrate is a product made of metal, a product made of inorganic material or a product made of polymeric material. A hard coating is silver-containing, copper-containing, or silver and copper-containing composite formed on surfaces of the aforementioned substrate through physical vapor deposition technology. However, the wear resistance of the coating of this invention is not good enough and the lasting effect of its bacterial function is poor.

### SUMMARY OF THE INVENTION

The object of the present invention is to provide a preparation method of an anti-bacterial coating on a plastic surface with a better anti-bacterial effect since the organic coating on the conventional plastic surface has some disadvantages including poor wear resistance and its bacterial function being not long enough.

The present invention comprises the following steps including:

1) putting a plastic substrate into a PVD vacuum device and creating vacuum environment to proceed an activated treatment.

In step 1), said plastic substrate can be thermoplastic or thermosetting plastic. Said thermoplastic can be selected from ABS, PC/ABS, HIPS, PC, PPO, PP, PERT, HDPE, PA6, PA66, ABS/TPU, glass reinforced PA6 and glass reinforced PP or other thermoplastic. Said thermosetting plastic can be selected from BMC or the like. The operational conditions for said activated treatment include ion source current being 0.3˜0.8 A, bias voltage being 80˜300 V, vacuum ratio being 50%˜80%, argon flow rate being 10˜200 SCCM, oxygen flow rate being 50˜300 SCCM, vacuum pressure in the oven being 0.1˜0.8 Pa, activation time being 5˜15 min to achieve the purpose of cleaning and activating the surfaces of the plastic substrate and to enhance the bounding force between bottom metallic layer and the substrate.

2) Coating an anti-bacterial metallic layer in vacuum on the activated surface of the plastic substrate.

In the step 2), the anti-bacterial metallic layer coated in vacuum on the activated surface of the plastic substrate can use arc process or medium frequency sputtering. The operational conditions of said arc process include current of target power supply being 50˜120 A, bias voltage being 80˜200V, argon flow rate being 20˜100 SCCM, nitrogen flow rate being 20˜100 SCCM, vacuum pressure in the oven being 0.1˜0.8 Pa and coating time being 5˜60 min. The operational conditions of said medium frequency sputtering include power of medium frequency power supply being 5˜9 kW, bias voltage being 80˜200 V, argon flow rate being 20˜100 SCCM, nitrogen flow rate being 20˜100 SCCM, vacuum pressure in the oven being 0.1˜0.8 Pa, coating time being 5˜60 min. The target for said anti-bacterial metallic coating can be at least one selected from Cu, Cr, Ag, Zn, Cu0.5-Zn0.5, Cr0.98-Ag0.2 alloy target or the like.

3) Spray coating an anti-bacterial middle coating on the sample coated with anti-bacterial metallic coating in vacuum obtained from step 2) to complete the anti-bacterial coating on the plastic surface, wherein the anti-bacterial middle coating is a coating with addition of organic anti-bacterial agents and inorganic anti-bacterial agents.

In step 3), said organic anti-bacterial agent is at least one anti-bacterial agent selected from vinyzene, dichlorooctylisothiazolinone (DCOIT) of Rohm & Haas Corporation, 3-(trimethoxy-silane) propylmethyldioctadecylammonium chloride, DC5700 of American Dow Corning Corporation, 10,10′-oxybis-phenoxarsine (OBPA) of Troy Corporation, phosphate ester composite and PolySept L type antibacterial agent of PolyChem Alloy or the like. Said inorganic anti-bacterial agent is at least one selected from nano-silver, nano-copper or the like. Said coating is at least one of UV (UV-cured) coating, baking (thermo-cured) coating, electrophoretic coating, electrostatic powder coating or the like. The spray coating procedure of said UV (UV-cured) coating comprises the following steps: (1) spray coating a layer of UV coating with addition of 1%-10% of anti-bacterial agent, wherein the thickness of the coating can be 10˜30 μm; (2) conveying the plastic piece into an infrared oven to level and dry the spray coating layer with drying temperature being 50˜70° C. and drying time being 3˜10 min; (3) spray coating layer after being leveled subjecting irradiation curing crosslinking for 10˜45 s in the UV curing oven. The spray coating procedure of said electrophoretic coating comprises the following steps: (1) electrophoretic depositing a layer of electrophoretic coating on the surface of a sample with a thickness of 10˜30 μm; (2) curing the electrophoretic coating layer in an oven with drying temperature being 140° C. and drying time being 20 min. The spray coating procedure of said electrostatic powder coating comprises the following steps: (1) spray coating a layer of powder coating on the surface of a sample with a thickness of 10˜30 μm; (2) conveying the plastic piece into an infrared oven to level and dry the spray coating layer with drying temperature being 50˜70° C. and drying time being 30˜40 min.

Comparing with the conventional anti-bacterial organic coating on the plastic surface, the present invention has significant advantages as follows.

The present invention utilizes PVD to coat antibacterial layer in vacuum to achieve the excellent anti-bacterial supplemental effect when the anti-bacterial effect of an organic coating is poor and also increase timeliness of bacterial activity and prolong life span of products with excellent anti-bacterial effect. Such surfaces of the plastic layer with double anti-bacterial layers have endured anti-bacterial, bacteria-inhibited effects. That is, utilizing PVD to coat antibacterial layer in vacuum offsets timeliness of bacterial activity of the organic anti-bacterial coating, which allows the products with double bacterial layers to have excellent anti-bacterial and bacteria-inhibited effects during their life spans. The anti-bacterial effect can not only be lasted for a long time, but also achieve high anti-bacterial and bacteria-inhibiting efficiency (antibacterial rate is more than 99%). The product has excellent function and superior appearance, which is suitable for bath products, electronic devices, domestic appliances, cars and other industries.

### BRIEF DESCRIPTION OF THE DRAWINGS

The invention, as well as its many advantages, may be further understood by the following detailed description and drawings in which:

FIG. 1 shows E. coli test results for example 1 in the present invention. In FIG. 1, (a) is survival E. coli of blank sample (100-time dilution), (b) is survival E. coli of anti-bacterial sample.

FIG. 2 shows Staphylococcus aureus test results for example 1 in the present invention. In FIG. 2, (a) is survival Staphylococcus aureus of blank sample (100-time dilution), (b) is survival Staphylococcus aureus of anti-bacterial sample.

### DETAILED DESCRIPTION OF THE INVENTION

### Example 1

An example of a PC/ABS mirror shell coated with a double-layer anti-bacterial coating has following procedure:

(1) A PC/ABS injection molded blank was put into a PVD vacuum device and vacuum environment was created. When the vacuum degree was up to 10⁻², the substrate was washed and activated (plasma glow). The operational conditions include ion source current being 0.3 A, bias voltage being 150 V, vacuum ratio being 80%, argon flow rate being 100 SCCM, oxygen flow rate being 200 SCCM, vacuum pressure in the oven being 0.4 Pa, activation time being 10 min to achieve the purpose of cleaning and activating the surfaces of the substrate and to enhance the bounding force between the metallic anti-bacterial layer and the substrate.

(2) The surface of the PC/ABS injection molded blank was coated with a metallic base coating in vacuum and the substrate surface was coated with an antibacterial metallic coating, which was a metallic anti-bacterial coating simultaneously deposited with three kinds of metals including copper, chromium and silver. The arc sputtering target was used to deposit chromium and silver. A cylindrical target for frequency sputtering was used as a pure copper target. The operational conditions include current of chromium target power supply being 60 A, current of silver target power supply being 80 A, power of medium frequency power supply of copper target being 5 kW, bias voltage being 120V, argon flow rate being 50 SCCM, nitrogen flow rate being 80 SCCM, vacuum pressure in the oven being 0.15 Pa and coating time being 5 min.

3) The sample coated with PVD metallic base coating was spray coated with an anti-bacterial middle coating, which was an UV coating with addition of inorganic anti-bacterial agents. Its procedure comprises the following procedure in sequence.

a. A layer of an UV coating with addition of 1% of nano-silver antibacterial agent was spray coated and the thickness of the layer is approximately 30 μm.

c. The plastic piece was conveyed into an infrared oven to level and dry the spray coating layer with drying temperature being 50° C. and drying time being 10 min.

d. spray coating layer after being leveled subjected irradiation curing crosslinking for 45 s in the UV curing oven.

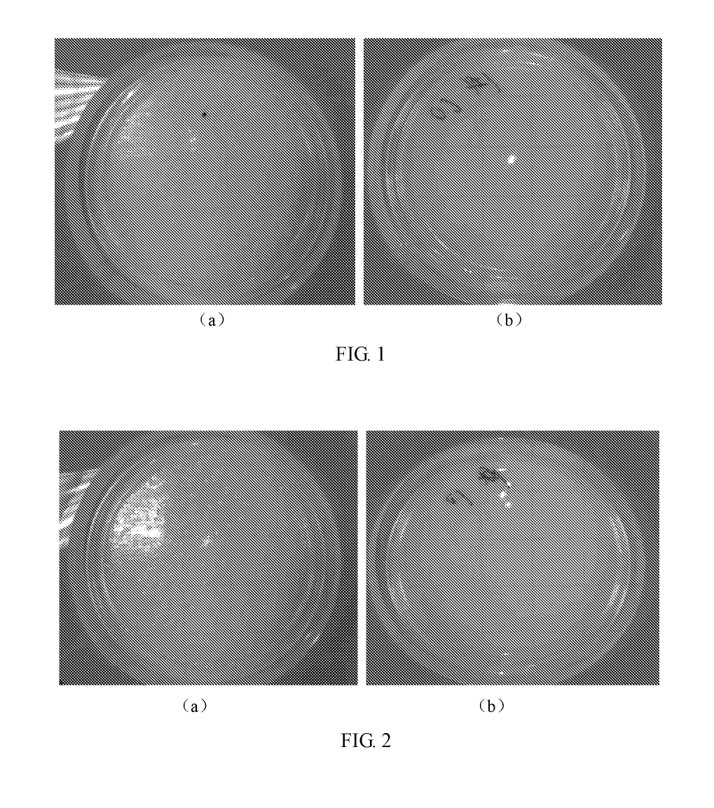

The sample was tested according to JIS Z2801:2000 Antimicrobial˜Test for antimicrobial activity and efficacy standard. The test results are shown in table 1 and the photographs of the anti-bacterial results have shown in FIGS. 1 and 2.

TABLE 1

| | | Inoculum Size of Bacteria at Different | | | |
|---|---|---|---|---|---|
| | | Contact Time after Being Washed | | | |
| | Concentration of | | inoculum size | inoculum size | |
| Name of | Bacteria Liquid | | of bacteria | of bacteria | Sterilizing |
| Tested Strain | (cfu/mL) | / | at 0 hr | at 24 hr | Rate (%) |
| E. coli | 8.3 × 10⁵ | Tested | / | <10 | 99.999 |
| ATCC 8739 | | Sample | | | |
| | | Controlled | 1.8 × 10⁵ | 8.6 × 10⁸ | |
| | | Sample | | | |
| Staphylococcus | 7.6 × 10⁵ | Tested | / | <10 | 99.99 |
| aureus | | Sample | | | |
| ATTCC6538P | | Controlled | 1.5 × 10⁵ | 5.6 × 10⁵ | |
| | | Sample | | | |

### Example 2

An example of a glass reinforced PPO plastic substrate coated with a double-layer anti-bacterial coating has following procedure:

(1) A glass reinforced PPO plastic substrate was put into a PVD vacuum device and vacuum environment was created. When the vacuum degree was up to 10⁻², the substrate was washed and activated (plasma glow). The operational conditions include ion source current being 0.8 A, bias voltage being 200 V, vacuum ratio being 50%, argon flow rate being 10 SCCM, oxygen flow rate being 300 SCCM, vacuum pressure in the oven being 0.5 Pa, activation time being 15 min to achieve the purpose of cleaning and activating the surfaces of the substrate and to enhance the bounding force between the anti-bacterial coating and the substrate.

(2) The surface of the glass reinforced PPO plastic substrate was coated with a metallic base coating in vacuum. The operational conditions for the medium frequency sputtering include power of medium frequency power supply being 6 kW, bias voltage being 80V, argon flow rate being 20 SCCM, bias voltage being 200V, argon flow rate being 100 SCCM, nitrogen flow rate being 50 SCCM vacuum pressure in the oven being 0.2 Pa and coating time being 50 min. The target used for the anti-bacterial coating is: Cr 0.98-Ag 0.2 alloy target.

3) The sample coated with PVD metallic base coating was spray coated with an anti-bacterial middle coating, which was an UV coating with addition of inorganic anti-bacterial agents. Its procedure comprises the following procedure in sequence.

a. A layer of an UV coating with addition of 10% of nano-copper antibacterial agent was spray coated and the thickness of the layer is approximately 10 μm.

c. The plastic piece was conveyed into an infrared oven to level and dry the spray coating layer with drying temperature being 70° C. and drying time being 3 min.

d. spray coating layer after being leveled subjected irradiation curing crosslinking for 10 s in the UV curing oven.

### Example 3

An example of a faucet made of PA6 with glass reinforced mineral powder (reinforced PA6) coated with a double-layer anti-bacterial coating has following procedure:

(1) A plastic piece made of PA6 with glass reinforced mineral powder (reinforced PA6) was put into a PVD vacuum device and vacuum environment was created. When the vacuum degree was up to 10⁻², the substrate was washed and activated (plasma glow). The operational conditions include ion source current being 0.6 A, bias voltage being 100 V, vacuum ratio being 70%, argon flow rate being 50 SCCM, oxygen flow rate being 100 SCCM, vacuum pressure in the oven being 0.3 Pa, activation time being 8 min to achieve the purpose of cleaning and activating the surfaces of the substrate and to enhance the bounding force between the anti-bacterial chloride removal coating and the substrate.

(2) The plastic substrate surface made of PA6 with glass reinforced mineral powder (reinforced PA6) was coated with an antibacterial metallic coating in vacuum and the substrate surface was coated with anti-bacterial metallic coating, which was an anti-bacterial metallic coating simultaneously deposited with three kinds of metals including copper, zinc and silver. The arc sputtering target was used as a pure silver target. A cylindrical target for frequency sputtering was used as a Cu0.5-Zn0.5 alloy target. The operational conditions include current of silver target power supply being 70 A, power of medium frequency power supply of Cu0.5-Zn0.5 alloy target being 9 kW, bias voltage being 200V, argon flow rate being 100 SCCM, nitrogen flow rate being 10 SCCM, vacuum pressure in the oven being 0.2 Pa and coating time being 30 min.

3) The sample coated with PVD metallic base coating was spray coated with an anti-bacterial middle coating, which was an UV coating with addition of inorganic anti-bacterial agents. Its procedure comprises the following procedure in sequence.

a. A layer of an UV coating with addition of 3% of DCOIT antibacterial agent of Rohm & Haas Corporation was spray coated and the thickness of the layer is approximately 20 μm.

c. The plastic piece was conveyed into an infrared oven to level and dry the spray coating layer with drying temperature being 70° C. and drying time being 8 min.

d. spray coating layer after being leveled subjected irradiation curing crosslinking for 30 s in the UV curing oven.

### Example 4

An example of a handle of a refrigerator, which was made of BMC thermosetting plastic blank, coated with a double-layer anti-bacterial coating has following procedure:

(1) A BMC thermosetting plastic blank was put into a PVD vacuum device and vacuum environment was created. When the vacuum degree was up to 10⁻², the substrate was washed and activated (plasma glow). The operational conditions include ion source current being 0.3 A, bias voltage being 80 V, vacuum ratio being 60%, argon flow rate being 100 SCCM, oxygen flow rate being 300 SCCM, vacuum pressure in the oven being 0.7 Pa, activation time being 10 min to achieve the purpose of cleaning and activating the surfaces of the substrate and to enhance the bounding force between the anti-bacterial coating and the substrate.

(2) The substrate surface of BMC thermosetting plastic blank was coated with an antibacterial metallic coating in vacuum and the substrate surface was coated with an anti-bacterial metallic coating in vacuum, which was an anti-bacterial metallic coating simultaneously deposited with three kinds of metals including copper, chromium and zinc. The arc sputtering targets were used as pure copper and pure zinc targets. A cylindrical target for frequency sputtering was used as pure silver target. The operational conditions include current of copper target power supply being 80 A, current of zinc target power supply being 50 A, power of medium frequency power supply of pure silver target being 5 kW, bias voltage being 150V, argon flow rate being 100 SCCM, nitrogen flow rate being 20 SCCM, vacuum pressure in the oven being 0.21 Pa and coating time being 15 min.

3) The sample coated with PVD metallic base coating was spray coated with an anti-bacterial middle coating, which was an UV coating with addition of organic anti-bacterial agents. Its procedure comprises the following procedure in sequence.

a. A layer of an UV coating with addition of 6% of 10,10′-oxybis-phenoxarsine (OBPA) of Troy Corporation was spray coated and the thickness of the layer is approximately 15 μm.

c. The plastic piece was conveyed into an infrared oven to level and dry the spray coating layer with drying temperature being 62° C. and drying time being 9 min.

d. spray coating layer after being leveled subjected irradiation curing crosslinking for 25 s in the UV curing oven.

### Example 5

An example of an ABS glass frame coated with a double-layer anti-bacterial coating has following procedure:

(1) A plastic substrate of an ABS glass frame was put into a PVD vacuum device and vacuum environment was created. When the vacuum degree was up to 10⁻², the substrate was washed and activated (plasma glow). The operational conditions include ion source current being 0.8 A, bias voltage being 120 V, vacuum ratio being 60%, argon flow rate being 80 SCCM, oxygen flow rate being 120 SCCM, vacuum pressure in the oven being 0.2 Pa, activation time being 5 min to achieve the purpose of cleaning and activating the surfaces of the substrate and to enhance the bounding force between the anti-bacterial chloride-removal coating and the substrate.

(2) The substrate surface of ABS glass frame made of plastic piece was coated with an antibacterial metallic coating in vacuum and the substrate surface was coated with an anti-bacterial metallic coating in vacuum, which was an anti-bacterial metallic coating simultaneously deposited with four kinds of metals including copper, zinc, chromium and silver. The arc sputtering targets were used as pure copper and pure chromium targets. A cylindrical target for frequency sputtering was used as Cu0.5-Zn0.5 alloy target. The operational conditions include current of chromium target power supply being 60 A, current of silver target power supply being 50 A, power of medium frequency power supply of Cu0.5-Zn0.5 alloy target being 8 kW, bias voltage being 100V, argon flow rate being 50 SCCM, nitrogen flow rate being 50 SCCM, vacuum pressure in the oven being 0.25 Pa and coating time being 25 min.

3) The sample coated with PVD metallic base coating was spray coated with an anti-bacterial middle coating, which was an UV coating with addition of organic anti-bacterial agents. Its procedure comprises the following procedure in sequence.

a. A layer of an UV coating with addition of 10% of “PolySept” of PolyChem Alloy was spray coated and the thickness of the layer is approximately 10 μm.

c. The plastic piece was conveyed into an infrared oven to level and dry the spray coating layer with drying temperature being 55° C. and drying time being 10 min.

d. spray coating layer after being leveled subjected irradiation curing crosslinking for 10 s in the UV curing oven.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A preparation method of an anti-bacterial coating on a plastic surface, characterized in that the method comprises the following steps including:
1) putting a plastic substrate into a PVD vacuum device and creating vacuum environment to proceed an activated treatment;
2) coating an anti-bacterial metallic layer in vacuum on the activated surface of the plastic substrate;
3) spray coating an anti-bacterial middle coating on the sample coated with anti-bacterial metallic coating in vacuum obtained from step 2) to complete the anti-bacterial coating on the plastic surface, wherein the anti-bacterial middle coating is a coating with addition of organic anti-bacterial agents and inorganic anti-bacterial agents.

2. The preparation method of an anti-bacterial coating on a plastic surface as claimed in claim 1, characterized in that in step 1), said plastic substrate is thermoplastic or thermosetting plastic; said thermoplastic is selected from ABS, PC/ABS, HIPS, PC, PPO, PP, PERT, HDPE, PA6, PA66, ABS/TPU, glass reinforced PA6 and glass reinforced PP; and said thermosetting plastic is selected from BMC.

3. The preparation method of an anti-bacterial coating on a plastic surface as claimed in claim 1, characterized in that in step 1), the operational conditions for said activated treatment include ion source current being 0.3˜0.8 A, bias voltage being 80˜300V, vacuum ratio being 50%˜80%, argon flow rate being 10˜200 SCCM, Oxygen flow rate being 50˜300 SCCM, vacuum pressure in the oven being 0.1˜0.8 Pa, activation time being 5˜15 min.

4. The preparation method of an anti-bacterial coating on a plastic surface as claimed in claim 1, characterized in that in step 2), said anti-bacterial metallic layer coated in vacuum on the activated surface of the plastic substrate uses arc process or medium frequency sputtering.

5. The preparation method of an anti-bacterial coating on a plastic surface as claimed in claim 4, characterized in that in step 2), the operational conditions of said arc process include current of target power supply being 50˜120 A, bias voltage being 80˜200V, argon flow rate being 20˜100 SCCM, nitrogen flow rate being 20˜100 SCCM, vacuum pressure in the oven being 0.1˜0.8 Pa and coating time being 5˜60 min; and the operational conditions of said medium frequency sputtering include power of medium frequency power supply being 5˜9 kW, bias voltage being 80˜200 V, argon flow rate being 20˜100 SCCM, nitrogen flow rate being 20˜100 SCCM, vacuum pressure in the oven being 0.1˜0.8 Pa, coating time being 5˜60 min.

6. The preparation method of an anti-bacterial coating on a plastic surface as claimed in claim 1, characterized in that in step 2), the target for said anti-bacterial metallic coating is at least one selected from Cu, Cr, Ag, Zn, Cu0.5-Zn0.5, Cr0.98-Ag0.2 alloy target.

7. The preparation method of an anti-bacterial coating on a plastic surface as claimed in claim 1, characterized in that in step 3), said organic anti-bacterial agent is at least one anti-bacterial agent selected from dichlorooctylisothiazolinone, 3-(trimethoxy-silane) propylmethyldioctadecylammonium chloride, DC5700, 10,10′-oxybis-phenoxarsine, phosphate ester composite, PolySept L type antibacterial agent.

8. The preparation method of an anti-bacterial coating on a plastic surface as claimed in claim 1, characterized in that in step 3), said inorganic anti-bacterial agent is at least one selected from nano-silver, nano-copper.

9. The preparation method of an anti-bacterial coating on a plastic surface as claimed in claim 1, characterized in that in step 3), said coating is at least one of UV coating, baking coating, electrophoretic coating, electrostatic powder coating.

10. The preparation method of an anti-bacterial coating on a plastic surface as claimed in claim 9, characterized in that
spray coating procedure of said UV coating comprises the following steps: (1) spray coating a layer of UV coating with addition of 1%˜10% of anti-bacterial agent, wherein the thickness of the coating can be 10˜30 μm; (2) conveying the plastic piece into an infrared oven to level and dry the spray coating layer with drying temperature being 50˜70° C. and drying time being 3˜10 min; (3) spray coating layer after being leveled subjecting irradiation curing crosslinking for 10˜45 s in the UV curing oven;
the spray coating procedure of said electrophoretic coating comprises the following steps: (1) electrophoretic depositing a layer of electrophoretic coating on the surface of a sample with a thickness of 10˜30 μm; (2) curing the electrophoretic coating layer in an oven with drying temperature being 140° C. and drying time being 20 min; and
the spray coating procedure of said electrostatic powder coating comprises the following steps: (1) spray coating a layer of powder coating on the surface of a sample with a thickness of 10˜30 μm; (2) conveying the plastic piece into an infrared oven to level and dry the spray coating layer with drying temperature being 50˜70° C. and drying time being 30˜40 min.
